(19) United States
(12) Patent Application Publication
(10) Pub. No.: US 2014/0182655 A1
(43) Pub. Date: Jul. 3, 2014

(54) MOUNTING PROCEDURE OF A HIGH-CONCENTRATION PHOTOVOLTAIC SOLAR MODULE AND MODULE THUS MOUNTED

(71) Applicant: ABENGOA SOLAR NEW TECHNOLOGIES, S.A., Sevilla (ES)

(72) Inventors: Sebastián E. CAPARRÓS JIMÉNEZ, Sevilla (ES); Antonio DE DIOS PARDO, Sevilla (ES); Carlos MARTÍN MAROTO, Sevilla (ES); Enrique JIMÉNEZ SÁEZ, Sevilla (ES); Adam BOTTS, Sevilla (ES)

(73) Assignee: ABENGOA SOLAR NEW TECHNOLOGIES, S.A., Sevilla (ES)

(21) Appl. No.: 13/784,285

(22) Filed: Mar. 4, 2013

(30) Foreign Application Priority Data
Dec. 27, 2012 (ES) P201201279

(51) Int. Cl. H01L 31/052

(52) U.S. Cl. CPC H01L 31/0524
USPC 136/246; 438/65

(57) ABSTRACT

Mounting procedure of a high-concentration photovoltaic solar module and module thus obtained, defined to carry out a simple final mounting based on a set of elements arriving from the factory in optimum packaging to facilitate the logistics, three being the main mounting sequences:

Sequence 1: optoelectronic system assembly

Sequence 2: mounting of the optoelectronic system at the base of the module, interconnecting and tests

Sequence 3: final assembly of the module, and wherein the module thus mounted comprises:
a series of equal optoelectronic systems placed in a matrix configuration and each one of them formed by secondary optics (1), a photovoltaic receiver (2), a thermal adhesive (3), a heat sink (4) and a fastening piece of the secondary optics composed by a body and a washer,
the structure of the module, and
the upper lens (9).

### TECHNICAL SECTOR OF THE INVENTION

The present invention describes a mounting procedure of a high-concentration photovoltaic solar module and the module thus mounted. Therefore, it belongs to the sector of photovoltaic solar energy.

### BACKGROUND OF THE INVENTION

Regarding the state of the art in designs of high-concentration photovoltaic modules (hereinafter HCPV), we find two important trends, which are distinguished by the distance between the light-concentrating optics and the receiver where the power is generated, all within the HCPV module.

There are module designs wherein the distance is relatively small. This causes the module to be shallow and relatively easy to transport, thus minimizing logistical costs. Normally, they are usually based on the use of small cells, which facilitates the thermal management of the module.

This type of designs has been developed by companies such as Soitec and Semprius, which use lenses, and companies such as Solfocus, which use mirrors.

The main inconvenience is that, in the case of using lenses, using small cells is necessary, which makes the assembly of a large number of pieces mandatory to obtain a determined power, which translates into higher automation costs and greater mounting difficulties. In addition, the cost of the materials tends to rise per generated watt, since the processing and manufacturing of the pieces increases considerably.

Regarding the use of mirrors, it allows using fairly larger cells, favoring automation costs. However, it severely increases the complexity of the system, thus increasing global costs.

There is another important trend, defined by the use of very large lenses with larger cells. The main advantages of this trend are cheaper receivers and optics However, the logistics of this model are much more complicated because the size of the module, as well as the volume occupied thereof, is much larger. in addition, the concentration and cell size limits need to be determined correctly in order to obtain an efficient and economical thermal dissipation.

In this typology we have companies such as Greenvolts, Amonix, Suntrix and Energy Innovations.

The objective of the invention described herein is to present a mounting procedure of a mirror-less high-concentration photovoltaic solar module, as well as the module thus mounted, which contains the main advantages of both trends and eliminates the weaknesses inherent to each one, which translates into more competitive costs. To achieve the foregoing, we need a modular, simple and fast mounting procedure, and also that is easily transportable, even in the case of large modules.

Therefore, the invention deals with a series of elements arriving from the factory prepared for their mounting and in optimal packaging to facilitate logistics, in order to only have to carry out its assembly on the field.

This way, said module and process are characterized by the low cost of the photovoltaic receivers and optics, wherein elements are also incorporate to minimize logistical costs and carry out an efficient and economical thermal management.

### DESCRIPTION OF THE INVENTION

The invention consists of a procedure to mount a high-concentration photovoltaic solar module and the module thus mounted.

The module to be mounted comprises a series of equal optoelectronic systems, placed in a matrix configuration, the structure of the module and the upper lenses.

Each optoelectronic sys m is in turn formed by the following elements: a heat sink, a thermal paste, a receiver, secondary optics, a washer and a fastening piece of the full optoelectronic system, which also protects the secondary optics and secures the bonding surface of the optoelectronic system to the module. The receiver, in general terms, comprises a cell, an electronic substrate (normally three layers conductor-insulator-conductor), diode, connectors and the internal connections of said elements.

The structure of the module comprises the following:
A lower base, where there are recesses to insert the previously mounted optoelectronic systems.
A lower frame and an upper frame. A metal base is inserted in the lower frame, on which the optoelectronic systems are placed, and in the upper frame the lens is bonded and the fastening pieces of the module are placed on the solar tracker.
Stiffening columns that connect the two frames and grant the appropriate structural resistance to the module.
Lateral covers adhered to the two frames to achieve a correct sealing of the system.

The mounting process of the module consists of three main sequences:

Sequence 1: optoelectronic system assembly

Sequence 2: mounting of the optoelectronic system at the base of the module

Sequence 3: final assembly of the module to obtain the finished product.

1. Description of sequence 1: comprises the following steps:
1.1. Dispensation of the thermal paste on the heat sink for the bonding of the receiver.
1.2. Placement of the photovoltaic receiver.
1.3. Bonding of the secondary optics to the photovoltaic cell existing in the receiver.

1.4. Placement of a washer on the secondary optics.

1.5. Placement of a fastening piece of the full optoelectronic system.

2. Description of sequence 2: comprises the following steps:
2.1. Mounting on the base of the module of each optoelectronic system obtained after carrying out sequence 1.
2.2. Interconnection of the different elements.
2.3. Placement of the protection against misalignment situations of the lens.

Next, the electrical tests are carried out to determine the power and final performance of the mounted base.

3. Description of sequence 3: comprises the following steps:
3.1. Positioning of the upper frame with the lens and the lower frame with the base and the optoelectronic systems placed on the same.
3.2. Insertion of central support bars to avoid the buckling of the lens.
3.3. Positioning of the stiffening columns and assembly with the upper and lower frames of the module.
3.4. Placement of the lateral covers and subsequent sealing of the set, thus obtaining the final module.

After the assembly of the full module, the airtightness test of the set and the final electrical test are carried out to verify the correct operation thereof.

This module design, as well as its mounting procedure, presents a series of advantages regarding what exists in the state of the art.

Each secondary receiver-optics set has an associated unitary heat sink. Said heat sink may have fiat or corrugated fins to increase the heat exchange area and thermal efficiency, since it is recommended that the cell temperature is kept at below 95° C.

Thermal paste is used to ensure the correct thermal transfer towards the heat sink and guarantee the electrical insulation, The foregoing allows not having any type of additional piece, such as pads or plastic electrical insulation pieces.

Fastening piece of the full optoelectronic system, which in addition protects the secondary optics and secures the bonding surface of the optoelectronic system to the module.

The combination of the elements described in this block allows a simple automatic mounting procedure, with machines and equipment that are easy to find on the market, at a competitive cost.

The shipment logistics of the pieces of the sets to be assembled is simple and economical, since the occupied volume is much smaller than if the module is sent fully assembled.

The defined operations are mechanical and very simple dispensation operations; therefore, they are very flexible to carry out at places near the final facilities, or even in small mounting lines where the market so requires it.

The pieces forming the mechanical structure of the module are flat, are very simple to manufacture and occupy very little volume when packed, which allows for a more efficient transport. All of the foregoing translates into competitive production and logistics costs.

### DESCRIPTION OF THE DRAWINGS

In order to complete the description being made and with the purpose of aiding a better comprehension of the invention, a set of drawings is attached which represent the following in an illustrative rather than limitative manner:

FIG. 1. Exploded perspective of the elements to be mounted in sequence 1.

FIG. 2. Product obtained after sequence 1, according to a first design.

FIG. 3. Product obtained after sequence 1, according to a second design.

FIG. 4. Product obtained after sequence 2, without protection pieces against the misalignment of the lens (base of the module+optoelectronic part).

FIG. 5. Product obtained after sequence 2 with protection pieces against the misalignment of the lens.

FIG. 6. Exploded perspective of the module without lateral covers.

FIG. 7. Module without the lens.

FIG. 8. Final module.

The references in the figures represent the following:

1. Heat sink

2. Thermal paste

3. Receiver

4. Secondary optics

5. Washer

6. Fastening piece of the optoelectronic system.

7. Fins

8. Base of the module

9. Protection against misalignment situations of the lens

10. Columns of the corner of the module

11 Central stiffening columns

12. Lateral covers

13. Lens

14. Ventilation valves

15. Fastening pieces of the module to the solar tracker

16. Full optoelectronic system in matrix form

### PREFERRED EMBODIMENT OF THE INVENTION

In order to achieve a greater comprehension of the invention, the following is a description of the mounting procedure of the high-concentration photovoltaic solar module, based on the figures.

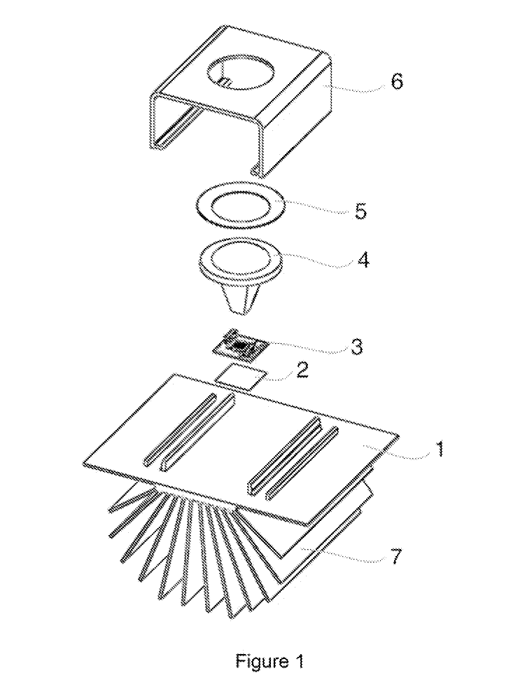

This mounting procedure is divided into three sequences. As observed in FIG. 1, the first sequence, which corresponds to the assembly of the optoelectronic system, comprises the following steps:

1.1. Dispensation of the thermal paste (2) on the heat sink (1) for the bonding of the receiver (3).

1.2. Placement of the photovoltaic receiver (3).

1.3. Bonding of the secondary optics (4) to the photovoltaic cell existing in the receiver (3).

1.4. Placement of a washer (5) on the secondary optics (4).

1.5. Placement of a fastening piece (6) of the full optoelectronic system.

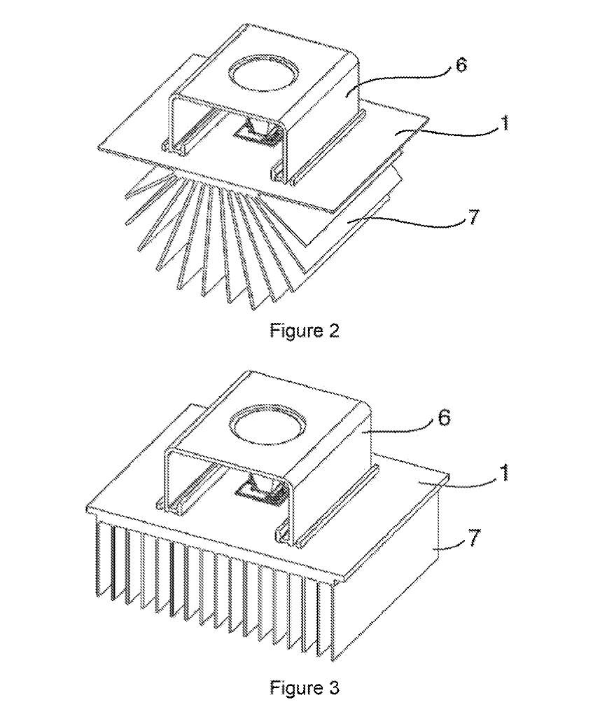

There are two design alternatives depending on how the fins (7) are placed in the heat sink (1), since they can be placed in the form of a fan (FIG. 2) or the parallelism between them may be kept (FIG. 3).

Sequence 2 comprises the following steps:

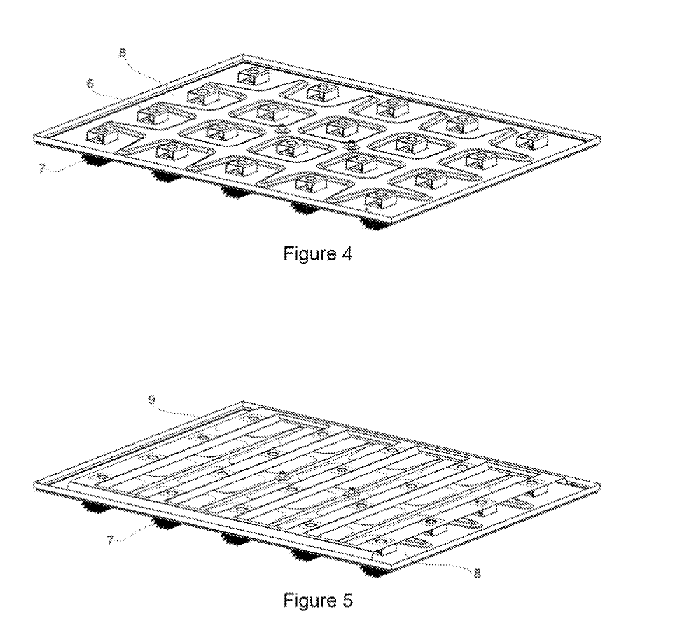

2.1. Mounting on the base of the module (8) of each optoelectronic system obtained after carrying out sequence 1 (FIG. 4).

2.2. Interconnection of the different elements.

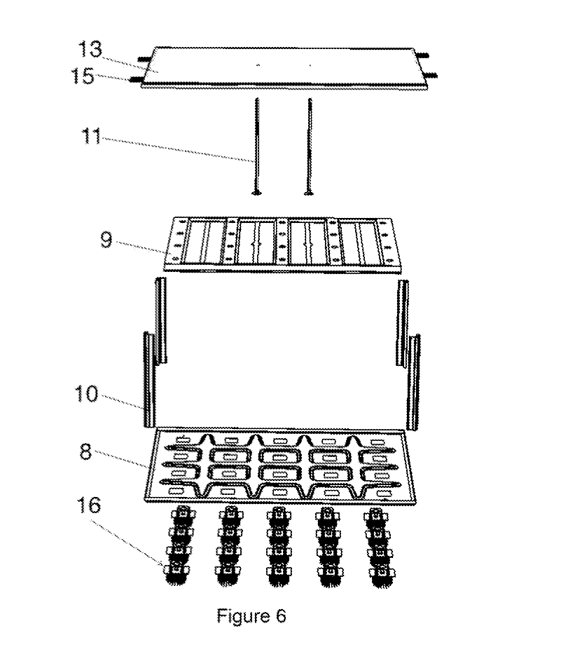

2.3. Placement of the protection against misalignment situations of the lens (9) (FIG. 5, without columns).

Next, the electrical tests are carried out to determine the power and final performance of the mounted base.

Sequence 3 comprises the following steps:

3.1. Positioning of the upper frame with the lens (13) and the lower frame with the base (8) and the optoelectronic systems placed on the same.

3.2. Insertion of bars of the central stiffening columns (11) to avoid the buckling of the lens (13).

3.3. Positioning of the corner stiffening columns (10) and assembly with the upper and lower frames of the module.

3.3. Placement of the lateral covers (12) and subsequent sealing of the set, thus obtaining the final module.

After the assembly of the full module, the airtightness test of the set and the final electrical test are carried out to verify the correct operation thereof.

FIG. 6 shows an exploded perspective of the module without lateral covers (12).

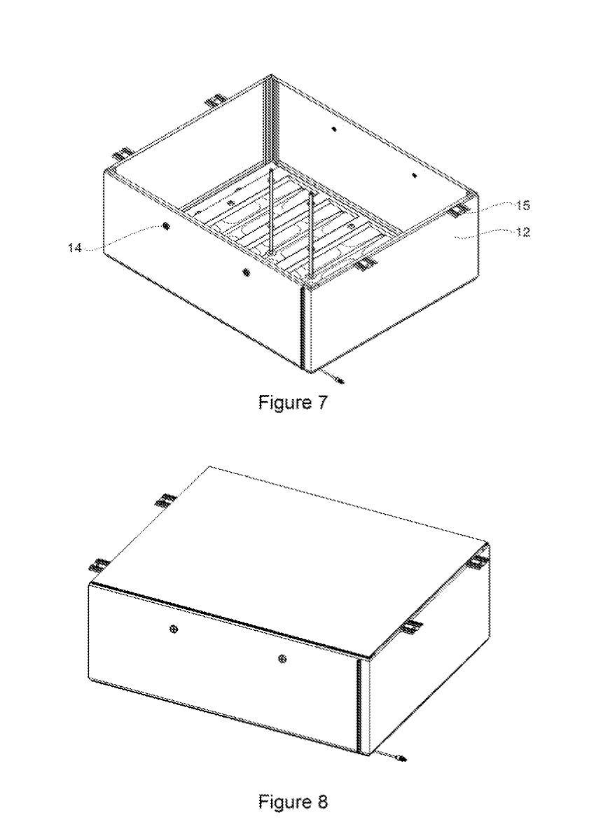

FIG. 7 shows the module without the lens and FIG. 8 shows the final module.

We can observe that the high-concentration photovoltaic solar module thus obtained comprises an optoelectronic system formed by secondary optics (4), a receiver (3), both joined by a thermal paste (2), it also has a heat sink (1) for each receiver (3), as well as a fastening piece of the optoelectronic system (6). All of the foregoing is placed on the base of the module (8), which is a flat sheet with recesses made for the insertion of the optoelectronic sets. Stiffening columns and central columns (11) are placed on the corners (10) of the base of the module, which help placing the lens (13) and avoid buckling, in addition to the lateral covers (12). The upper part of the module has some upper fastening pieces (15) whose purpose is to fasten the module in the solar tracker and some ventilation valves (14) with a membrane that prevents dirt and liquid water from entering. All the set is sealed to achieve air-tightness. This system is especially indicated for its use in high-concentration photovoltaic solar modules, but its use in other fields of the industry that require similar characteristics is not ruled out.

1. Mounting procedure of a high-concentration photovoltaic solar module of those that comprise a series of equal optoelectronic systems placed in a matrix, the structure of the module, and the upper lens and each optoelectronic system formed, among other elements, by secondary optics, a receiver, a heat sink and a fastening piece and wherein it comprises the following sequences:
Sequence 1: assembly of the different elements that form the optoelectronic systems,
Sequence 2: mounting of each optoelectronic system on the base of the module, interconnecting and protecting against misalignment situations,
Sequence 3: obtaining the final module, placing some central and corner stiffening columns, some lateral covers and the upper lens.

2. Mounting procedure of a high-concentration photovoltaic solar module according to claim 1, wherein sequence 1 comprises the following steps:
1.1. Dispensation of the thermal paste on the heat sink for the bonding of the receiver.
1.2. Placement of the photovoltaic receiver.
1.3. Bonding of the secondary optics to the photovoltaic cell existing in the receiver.
1.4. Placement of a washer on the secondary optics.
1.5. Placement of a fastening piece of the full optoelectronic system.

3. Mounting procedure of a high-concentration photovoltaic solar module according to claim 2, wherein sequence 2 comprises the following steps:
2.1. Mounting on the base of the module of each optoelectronic system obtained after carrying out sequence 1.
2.2. Interconnection of the different elements.
2.3. Placement of some protection against misalignment situations of the lens.

4. Mounting procedure of a high-concentration photovoltaic solar module according to claim 3, wherein sequence 3 comprises the following steps:
3.1 Positioning of the upper frame with the lens and the lower frame with the base and the optoelectronic systems placed on the same.
3.2. Insertion of the support bars of the central stiffening columns to avoid the buckling of the lens.
3.3. Positioning of the corner stiffening columns and assembly with the upper and lower frames of the module.
3.3. Placement of the lateral covers and subsequent sealing of the set, thus obtaining the final module.

5. High-concentration photovoltaic solar module obtained according to the procedure described in claim 1, wherein it comprises a series of optoelectronic systems each one formed, in turn, by secondary optics, and a receiver, both connected by a thermal paste, a heat sink for each receiver, as well as a fastening piece of the optoelectronic system; all placed on the base of the module on which some stiffening columns are also placed that support the lens, as well as the lateral covers.

6. High-concentration photovoltaic solar module obtained according to claim 5, wherein the base of the module is a flat sheet with recesses for the insertion of the optoelectronic systems.

7. High-concentration photovoltaic solar module obtained according to claim 5 wherein the module, in its upper part, has some upper fastening pieces whose purpose is to fasten the module to the solar tracker.
